(19) United States
(12) Patent Application Publication
(10) Pub. No.: US 2003/0128600 A1
(43) Pub. Date: Jul. 10, 2003

(54) Energy-saving writing into an optical data store

(76) Inventors: Steffen Noehte, Weinheim (DE); Jorn Leiber, Hamburg (DE)

Correspondence Address: Baker & Daniels, 111 East Wayne Street Suite 800, Fort Wayne, IN, 46803, US

(21) Appl. No.: 10/240,631

(22) PCT Filed: Mar. 8, 2001
(86) PCT No.: PCT/EP01/02602

(30) Foreign Application Priority Data
Apr. 4, 2000 (DE) 100165850

(51) Int. Cl. G11C 7/00

(52) U.S. Cl. 365/200

(57) ABSTRACT

An optical data store is proposed comprising a storage medium and a light source for storing data in the storage medium. The invention provides for the storage medium to be formed for the storage of data by heating above a threshold temperature, and the light source to be designed to focus long wave light for the purpose of heating the storage medium to a temperature below the threshold temperature and to focus short wave light, with which only the storage medium previously heated by long waves can be heated to a temperature above the threshold temperature.

The present invention relates to the preamble of the independent claim. The present invention is therefore concerned with optical data stores.

Optical data stores are known per se. Examples of this are the DVD, the CD-ROM and their variants which can be rewritten once or repeatedly. Furthermore, it is known that data can be stored on wound polymer films, for example see DE U 29816802.2.

In the data medium last mentioned, polymer material is heated point by point as a result of irradiation of a beam of light, which changes the optical property of the polymer material. This change in the optical properties can subsequently be detected as a change in the reflective power and can be evaluated. In this case, the change occurs only when specific minimum heating of the polymer material is performed.

In the course of miniaturizing electronic devices such as laptops, electronic notebooks and so on, it is desired to reduce the energy needed to write and read an optical data store to the greatest extent possible, in order therefore also to reduce the requirements on the power supply.

The object of the present invention is to provide innovation for commercial application.

The achievement of this object is claimed independently. Preferred embodiments will be found in the subclaims.

A significant aspect of the invention is thus to be seen in the fact that an optical data store comprising a storage medium and a light source for storing data in the storage medium is provided, in which the storage medium is designed to be heated above a threshold temperature for the storage of data by heating, and the light source is designed to focus long wave light for the purpose of heating the storage medium to a temperature below the threshold temperature and to focus short wave light with which only the storage medium preheated by long waves can be heated to a temperature above the threshold temperature.

A significant aspect of the invention is thus initially to be seen in choosing the storage medium with a threshold temperature which must be exceeded to store data, and then radiating the light in by means of two different wavelengths, in order in this way to heat the storage medium specifically. This procedure has a number of advantages. First of all, the long wave light can be provided with a higher efficiency, so that the total outlay on energy for the heating of the storage medium is lower. In addition, the intensity of the short wave light may be lower, it being possible in particular for the same or virtually the same intensity to be selected as during reading. This makes it possible to use the light source for short wave light with only low writing powers even for writing. Although the long wave light is naturally less easy to focus, nevertheless with the light source proposed, a very high writing density is made possible, since it is readily possible to heat up only a small area above the threshold temperature within a somewhat extended storage medium area heated by long wave light.

The storage medium will preferably be a polymer material which, in particular, is arranged in multiple layers. The multiple-layer feature can be obtained by stacking a plurality of storage layers one above another or winding up the polymer material, see in particular DE U 29816802.2.

In the case of multilayer or wound storage medium construction, it is preferred for there to be provided, between the polymer layers, a layer which reduces the reflection and which, in particular, can be chosen in such a way that both reflections of long wave and of short wave light are reduced.

In order to permit the heating of the storage medium, an absorber is preferably provided. This absorber can be applied as a varnish or coating on a polymer material substrate, or can be integrated in the polymer material itself or implemented by the latter. Here, the absorber is preferably chosen such that it absorbs short wave light intensely only when it has already been heated. In order to make this heating possible, the absorber has a high absorption in the range of the long wave light. Here, the storage medium can be heated indirectly to the temperature below the threshold temperature, specifically by means of the heat flowing into the environment from the absorber. The absorber is preferably chosen in such a way that it can absorb long wave light as far as a wavelength located at an absorption edge, it being possible for the position of the absorption edge to be shifted toward the short wave by heating. In this case, the heating with long wave light in the optical data store of the present invention is preferably so intensive, and the wavelength of the short wave light is selected, such that only the heated absorber becomes absorbent to the short wave light after or during irradiation with the long wave light. The absorber can be a thermochromic material.

It is preferred for the emitted long wave light to lie in the infrared, to be specific typically in the wavelength range between 800 and 1200 μm. The emitted short wave light will lie in the visible range.

For the emission of the light, laser diodes are preferably provided. In this case, separate laser diodes can be provided for long wave and short wave light, which simplifies their procurement. In such a case, a coupling unit can be provided, for example in the form of a partially transparent reflector, in order to lead the light of different wavelengths from the diodes together before it is focused onto the storage medium.

In a preferred exemplary embodiment, a means of temperature measurement, in particular without contact, is provided, with which the temperature of the storage medium is determined. This can be carried out, for example, by the intensity of the infrared or long wave light reflected back being determined. The temperature measurement can then be used to control the power of the infrared laser to a desired level, in order that the temperature of the storage medium can be moved close to the threshold. Although the basic concept of radiating light of two different wavelengths into the storage medium in order to effect the storage of data in the medium already leads to a high degree of independence of the ambient temperature being achieved in particular independence of temperature-induced and undesired variation of the absorption coefficient of an absorber used, the intensity of the light radiated in can always be adjusted by means of the measurement of the IR back reflection such that storage is carried out independently of the temperature with the minimum required and nevertheless sufficient energy.

In a preferred exemplary embodiment, the intensity of the long wave to short wave light lies in the range of 2:1, in particular preferably 5:1. The intensity of the short wave light therefore always has to be kept considerably lower, which is also advantageous with regard to the investment required for the light sources, such as laser diodes.

It should be pointed out that protection is also requested for a method of storing data on a storage medium, in which data can be stored optically by heating above a threshold temperature, characterized in that first of all long wave light is radiated in in order to heat the storage medium to a temperature below the threshold temperature, and then short wave light is radiated in in order to heat the storage medium previously heated with long wave light to a temperature above the threshold temperature.

The invention will be described in the following text merely by way of example, by using the drawing, in which:

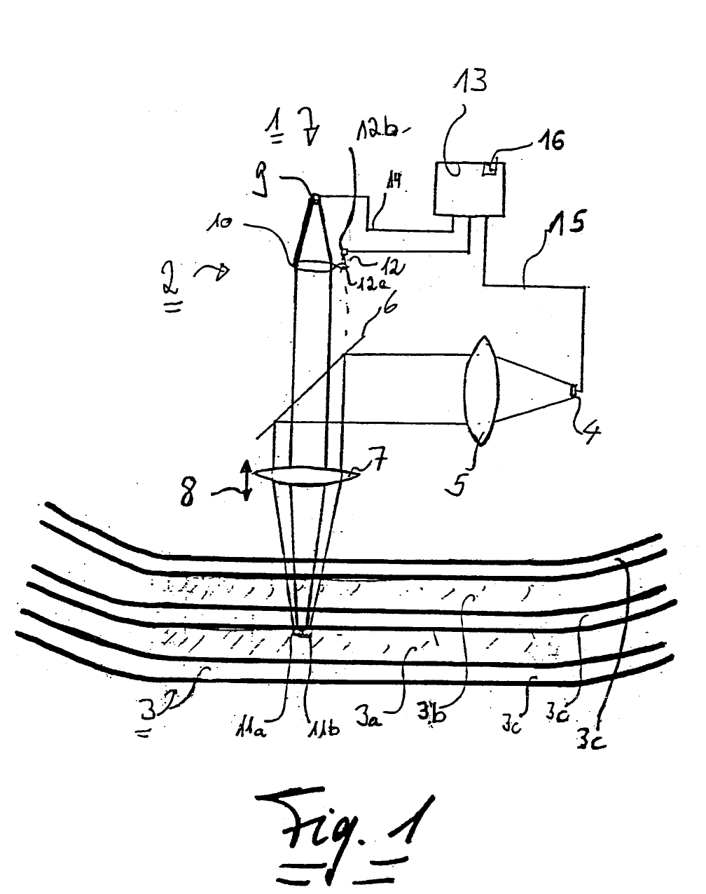

FIG. 1 shows an optical data storage device according to the present invention.

According to FIG. 1, a data storage device designated generally by 1 comprises a light source 2, whose light is focused onto a storage medium 3. Light source 2 and storage medium 3 can be moved relative to each other by rotation by means of a motor.

The storage medium 3 is built up from a large number of layers of stretched PMMAs wound one above another. In the figure, only two layers 3a, 3b are shown for reasons of illustration. Provided between the PMMA layers is a layer 3c which ensures the adhesion of the layers 3, 3b of the polymer material and, at the same time, is highly transparent and has virtually the same calculation index as the polymer material.

The light source 2 comprises an IR laser diode 4, whose light, after collimation by appropriate optics 5, is deflected onto a beam splitter 6 and through focusing optics 7. The focusing optics 7 focus the light onto one of the layers 3a, 3b, which can be determined as desired, and for this purpose can be displaced, as indicated by arrow 8.

The light source 2 further comprises a laser diode 9 for visible and therefore relatively short wave light, whose laser radiation is collimated by collimation optics 10 and is then directed onto the focusing optics 7, passing through the beam splitter 6. The beam splitter 6, through which firstly the visible light from the laser diode 9 passes and at which, secondly, the IR radiation from the IR laser diode 4 is reflected onto the focusing optics 7, therefore serves as a coupling unit for coupling the long wave and short wave light.

The focusing optics 7 are chosen in such a way that the focal spot which can be achieved with the IR light under optimum conditions is larger than that which can be achieved with the visible light from the laser diode 9, as indicated by the areas 11a, 11b of different size of the focal spot 11.

Incorporated in the polymer layer is a thermochromic absorber which, in the cold state, absorbs only in the infrared and, following its heating, shifts its absorption edge in such a way that it can also absorb the visible laser light emitted by the laser diode 9.

The optical data store further comprises a temperature sensor arrangement 12, which registers the temperature of the polymer material in the focal spot optically. For this purpose, the infrared light reflected back from the focal spot behind the beam splitter 6 is deflected by a small lens 12a onto a photoelement 12b which is sensitive to the infrared radiation. The photoelement 12b is connected to a controller 13, which also provides the laser diode power via lines 14 and 15. The controller 13 is designed such that the energy fed to the laser diode 4 via line 15 can be varied.

The controller further has a data input 16, via which the data to be stored is received in binary form.

The optical data storage device operates as follows:

With the light source and storage medium moving relative to each other, data to be stored is provided at the input 16 to the controller 13. The IR laser diode 4 is then excited so intensely via line 15 that the emitted IR laser radiation which, following collimation, passes through the optics 5 and the passage through the coupling unit 6 and the focusing unit 7, is sufficient to heat the polymer material in the desired layer, in which writing is to take place, to a temperature at which the absorber absorbs in the visible. Reaching this temperature is registered by the temperature sensor 12 and reported to the controller 13. In the event of a high ambient temperature, such as 45° C., which can be reached in a car, the energy fed to the laser diode 4 via the line 15 is considerably lower than is the case in free air under winter conditions.

Then in accordance with the modulation required to store the data 16, light from the laser diode 9 is radiated onto the heated medium by exciting said laser diode 9 via the line 14. The laser light from the laser diode 9 passes through the optics 10, the coupling unit 6 and is directed onto the preheated polymer layer colinearly with the infrared light from the laser diode 4. Because of the preheating of the absorber, its absorption edge has been shifted to such an extent that it can then also absorb visible light. The additional energy radiated in is sufficient to change the polymer material in a nonvolatile manner. The spot at which this nonvolatile change is achieved in this case depends on the modulation mode of the laser diode 9 and the relative speed at which the storage medium 9 and the focus or focal point 11 are moved in relation to each other. The heating of the polymer material to a temperature above the threshold temperature is, however, physically lower than the range in which the polymer material is warmed up close to the threshold temperature. This is caused by the fact that the short wave light from the laser diode 9 can be focused substantially better than the long wave light from the laser diode 4. In this way, in spite of the very small focal spot and, associated with this, the high storage density, the arrangement nevertheless permits energy-saving storage of large quantities of data.

1. An optical data store comprising a storage medium and a light source for storing data in the storage medium, characterized in that the storage medium is designed to store data by being heated above a threshold temperature, and the light source is designed to focus long wave light for the purpose of heating the storage medium to a temperature below the threshold temperature and to focus short wave light, with which only the storage medium preheated with long waves can be heated to a temperature above the threshold temperature.

2. The optical data store as claimed in claim 1, characterized in that the storage medium is a polymer material and/or comprises polymer material substrates.

3. The optical data store as claimed in the preceding claim, characterized in that the polymer material is built up from many layers.

4. The optical data store as claimed in claim 1, characterized in that the polymer material is wound.

5. The optical data store as claimed in either of claims 3 and 4, characterized in that a layer that reduces reflection is arranged between the polymer layers.

6. The optical data store as claimed in one of the preceding claims, characterized in that an absorber is provided in the polymer layers.

7. The optical data store as claimed in the preceding claim, characterized in that the absorber is applied as an absorber layer on the polymer material.

8. The optical data store as claimed in the preceding claim, characterized in that the polymer material itself absorbs.

9. The optical data store as claimed in the preceding claim, characterized in that the absorber is chosen such that it absorbs long wave light in the unheated state and, in the heated state, has a significantly increased absorption for short wave light.

10. The optical data store as claimed in the preceding claim, characterized in that the absorber is a thermochromic material.

11. The optical data store as claimed in one of the preceding claims, characterized in that the emitted long wave light from the light source lies in the infrared, in particular at a wavelength between 800 and 1200 μm.

12. The optical data store as claimed in one of the preceding claims, characterized in that the emitted short wave light lies in the visible range.

13. The optical data store as claimed in one of the preceding claims, characterized in that a laser diode is provided for the emission of at least long wave or short wave light.

14. The optical data store as claimed in the preceding claim, characterized in that in each case a separate laser diode is provided for the emission of long wave and short wave light.

15. The optical data store as claimed in one of the preceding claims, characterized in that a coupling unit is provided in order to guide the light at different wavelengths together before it is focused onto the storage medium, in particular to permit coaxial focusing thereof.

16. The optical data store as claimed in one of the preceding claims, characterized in that a means of measuring temperature, in particular without contact, is provided in order to determine the temperature of the storage medium.

17. The optical data store as claimed in one of the preceding claims, characterized in that a controller is provided in order to vary the intensity of the infrared radiation as a function of the registered temperature.

18. The optical data store as claimed in one of the preceding claims, characterized in that the ratio of the intensity of long wave to short wave light radiated in is at least 2:1, in particular 4:1.

19. An optical data storage device comprising a light source for storing data in a storage medium which is formed for the storage of data by heating above a threshold temperature, characterized in that the light source is designed to focus long wave light for the purpose of heating the storage medium to a temperature below the threshold temperature and to focus short wave light, with which only the storage medium previously heated by long waves can be heated to a temperature above the threshold temperature.

20. A storage medium for storing data by heating above a threshold temperature, characterized in that an absorber is provided on or in the storage medium, absorbs light of a first wavelength for heating the storage medium to a temperature below the threshold temperature and, in the heated state, also absorbs light of a second wavelength, in order with the latter to achieve heating to a temperature above the threshold temperature.

21. A method for the optical storage of data, characterized in that a storage medium is provided which can store data in a nonvolatile manner by heating above a threshold temperature, a light source with long wave light is focused onto the storage medium for the purpose of heating the storage medium to a temperature below the threshold temperature and then short wave light is radiated onto the storage medium previously heated with long wave radiation, in order to heat said storage medium to a temperature above the threshold temperature.
